(19) United States
(12) Patent Application Publication
(10) Pub. No.: US 2013/0085695 A1
(43) Pub. Date: Apr. 4, 2013

(54) BATTERY STATE MEASURING METHOD AND APPARATUS, AND ELECTRONIC APPARATUS

(71) Applicant: Kimitoshi ONO, Tokyo (JP)

(72) Inventor: Kimitoshi ONO, Tokyo (JP)

(73) Assignee: MITSUMI ELECTRIC CO., LTD., Tokyo (JP)

(21) Appl. No.: 13/623,357

(22) Filed: Sep. 20, 2012

(30) Foreign Application Priority Data
Sep. 29, 2011 (JP) 2011-215603

(51) Int. Cl. G01R 31/36

(52) U.S. Cl. 702/63

(57) ABSTRACT

A battery state measuring method computes a battery voltage at a time when charging or discharge of a battery stops, corresponding to a charging rate of a unit time before, based on a first battery characteristic. The method further computes a variation per unit time of the charging rate, corresponding to a voltage difference between the detected and computed battery voltages, based on a second battery characteristic, and computes a charging rate of the unit time after, using the charging rate of the unit time before and the computed variation.

### CROSS-REFERENCE TO RELATED APPLICATIONS

This application is based upon and claims the benefit of priority of the prior Japanese Patent Application No. 2011-215603, filed on Sep. 29, 2011, the entire contents of which are incorporated herein by reference.

### BACKGROUND OF THE INVENTION

1. Field of the Invention

The present invention relates to techniques for measuring a state of a rechargeable battery (or secondary cell).

2. Description of the Related Art

Conventionally, there is a known apparatus that computes a remaining capacity of a battery by detecting an open-circuit voltage of the battery, and comparing the detected open-circuit voltage with data representing a relationship between the open-circuit voltage of the battery and the remaining capacity of the battery. Such an apparatus is proposed in a Japanese Laid-Open Patent Publication No. 3-180783, for example.

However, the state (remaining capacity state) of the rechargeable battery may vary depending on a magnitude of a load current, even when the battery voltage is the same. Hence, according to the conventional apparatus described above, the accuracy with which the remaining capacity state of the rechargeable battery is estimated may be poor in some cases.

### SUMMARY OF THE INVENTION

Accordingly, it is an object in one embodiment of the present invention to provide a battery state measuring method, a battery state measuring apparatus, and an electronic apparatus, which may estimate the remaining capacity state of the rechargeable battery with a high accuracy.

According to one aspect of the present invention, a battery state measuring method may include detecting a battery voltage of a rechargeable battery; computing a battery voltage at a time when charging or discharge of the rechargeable battery stops, corresponding to a charging rate of the rechargeable battery of a unit time before, based on a first battery characteristic that determines a relationship between the charging rate and the battery voltage at the time when the charging or discharge of the rechargeable battery stops; computing a voltage difference between the battery voltage detected by the detecting and the battery voltage computed by the battery voltage computing; computing a variation per unit time of the charging rate of the rechargeable battery, corresponding to the voltage difference computed by the voltage difference computing, based on a second battery characteristic that determines a relationship of a voltage difference between the battery voltage at the time when the charging or discharge of the rechargeable battery stops and the battery voltage detected by the detecting, and a variation per unit time of the charging rate of the rechargeable battery; and computing a charging rate of the rechargeable battery of the unit time after, using the charging rate of the rechargeable battery of the unit time before and the variation computed by the variation computing.

According to one aspect of the present invention, a battery state measuring apparatus may include a voltage detector configured to detect a battery voltage of a rechargeable battery; a voltage computing unit configured to compute a battery voltage at a time when charging or discharge of the rechargeable battery stops, corresponding to a charging rate of the rechargeable battery of a unit time before, based on a first battery characteristic that determines a relationship between the charging rate and the battery voltage at the time when the charging or discharge of the rechargeable battery stops; a voltage difference computing unit configured to compute a voltage difference between the battery voltage detected by the voltage detector and the battery voltage computed by the voltage computing unit; a variation computing unit configured to compute a variation per unit time of the charging rate of the rechargeable battery, corresponding to the voltage difference computed by the voltage difference computing unit, based on a second battery characteristic that determines a relationship of a voltage difference between the battery voltage at the time when the charging or discharge of the rechargeable battery stops and the battery voltage detected by the voltage detector, and a variation per unit time of the charging rate of the rechargeable battery; and a charging rate computing unit configured to compute a charging rate of the rechargeable battery of the unit time after, using the charging rate of the rechargeable battery of the unit time before and the variation computed by the variation computing unit.

According to one aspect of the present invention, a battery protection unit, or a battery pack, or an electronic apparatus may include the battery state measuring apparatus described above.

### BRIEF DESCRIPTION OF THE DRAWINGS

FIG. 1 is a block diagram illustrating an example of a structure of a measuring circuit within a battery state measuring state in an embodiment of the present invention;

FIG. 2 is a diagram illustrating an example of a relationship between a RSOC (Relative State Of Charge) and a battery voltage at the time of charging and discharge of a rechargeable battery;

FIG. 3 is a flow chart for explaining a first computing example to compute the present RSOC;

FIG. 4 is a diagram illustrating another example of the relationship between the RSOC and the battery voltage at the time of charging and discharge of the rechargeable battery; and

FIG. 5 is a flow chart for explaining a second computing example to compute the present RSOC.

### DETAILED DESCRIPTION OF THE PREFERRED EMBODIMENTS

A description will be given of embodiments of the present invention, by referring to the drawings.

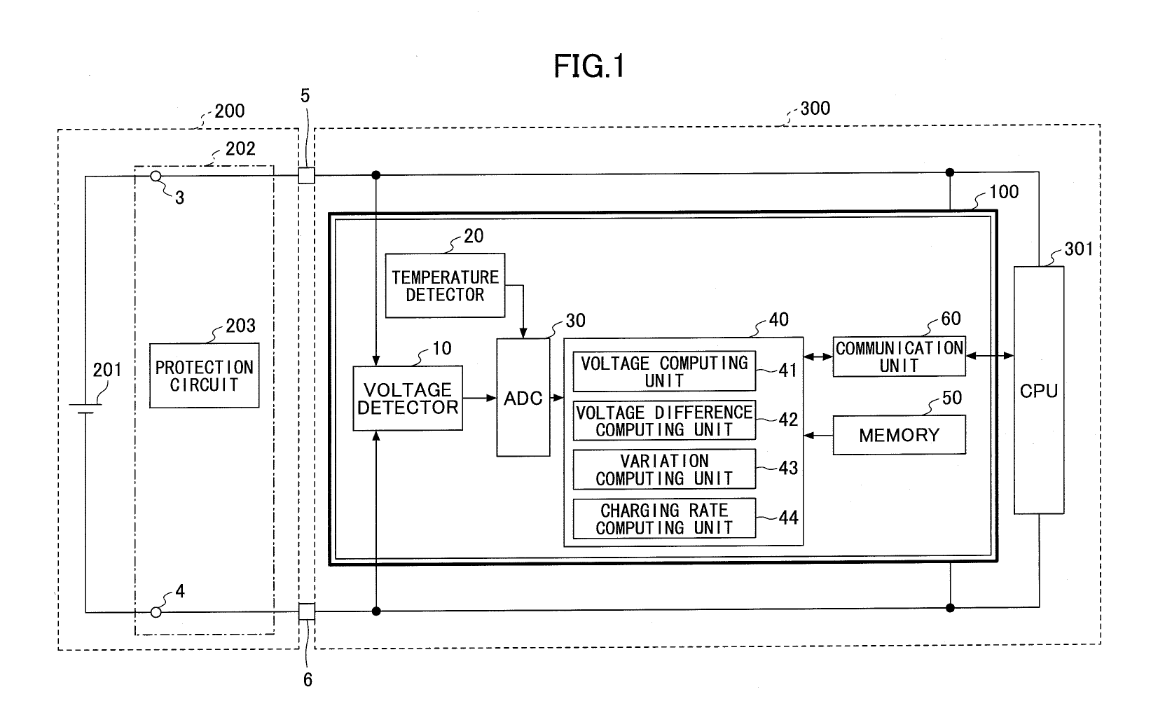

FIG. 1 is a block diagram illustrating an example of a structure of a measuring circuit within a battery state measuring state in an embodiment of the present invention. A measuring circuit 100 is an example of an IC (Integrated Circuit) that measures a remaining capacity state of a rechargeable battery 201. Examples of the rechargeable battery 201 include a lithium-ion battery, a nickel-hydrogen battery, and the like. The measuring circuit 100 may be provided within an electronic apparatus 300 that receives a supply of power from the rechargeable battery 201. Examples of the electronic apparatus 300 include electronic apparatuses, such as portable terminals (mobile phones, portable video game machines, information terminals, portable music and/or video players, etc.), video game consoles, computers, headsets, cameras, and the like.

The rechargeable battery 201 may be provided within a battery pack 200, and the battery pack 200 may be provided within the electronic apparatus 300 or be externally connected to the electronic apparatus 300. The rechargeable battery 201 may supply power to the electronic apparatus 300 via load connecting terminals 5 and 6, and may be charged by a charging unit that is not illustrated and is connected to the load connecting terminals 5 and 6. The battery pack 200 may include the rechargeable battery 201, and a protection module 202 that is connected to the rechargeable battery 201 via battery connecting terminals 3 and 4. The protection module 202 is an example of a battery protection unit, and may include a protection circuit 203 to protect the rechargeable battery 201 from at least one of abnormal states including an over-current state, over-charging state, over-discharge state, and the like.

The measuring circuit 100 may include a voltage detector 100, a temperature detector 20, an ADC (Analog-to-Digital Converter) 30, a battery capacity manager 40, a memory 50, and a communication unit 60.

The voltage detector 10 detects the battery voltage across both terminals of the rechargeable battery 201, and outputs to the ADC 30 an analog voltage corresponding to the detected battery voltage value.

The temperature detector 20 detects an ambient temperature of the rechargeable battery 201, and outputs to the ADC 30 an analog voltage corresponding to the detected temperature value. The temperature detector 20 may detect the temperature of the measuring circuit 100 or the electronic apparatus 30, as the ambient temperature of the rechargeable battery 201. In addition, the temperature detector 20 may detect the temperature of the rechargeable battery 201 itself, or may detect the temperature inside the battery pack 200.

The ADC 30 converts the output analog voltages of the voltage detector 10 and the temperature detector 20 into digital values, and outputs the digital values to the battery capacity manager 40.

The battery capacity manager 40 is an example of a processing unit that estimates the remaining capacity state of the rechargeable battery 201, based on the battery voltage of the rechargeable battery 201 detected by the voltage detector 10, the temperature of the rechargeable battery 201 detected by the temperature detector 20, and characteristic data representing battery characteristics of the rechargeable battery 201 and are prestored in the memory 50. The battery capacity manager 40 may include a voltage computing unit 41, a voltage difference computing unit 42, a variation computing unit 43, and a charging rate computing unit 44. A description of the computing units 41 through 44 will be given later in the specification. For example, the battery capacity manager 40 may be formed by a processing unit, such as a microcomputer., and the memory 50 may be formed by a rewritable nonvolatile memory, such as a EEPROM (Electrically Erasable Programmable Read Only Memory).

The communication unit 60 is an example of an interface to transmit the battery state, such as the remaining capacity state of the rechargeable battery 201, with respect to a control unit such as a CPU (Central Processing Unit) 301 provided within the electronic apparatus 300. The control unit such as the CPU 301 may execute predetermined control operations, such as displaying the remaining capacity state of the rechargeable batter 201 with respect to a user, based on the battery state such as the remaining capacity state of the rechargeable battery 201 acquired from the measuring circuit 100.

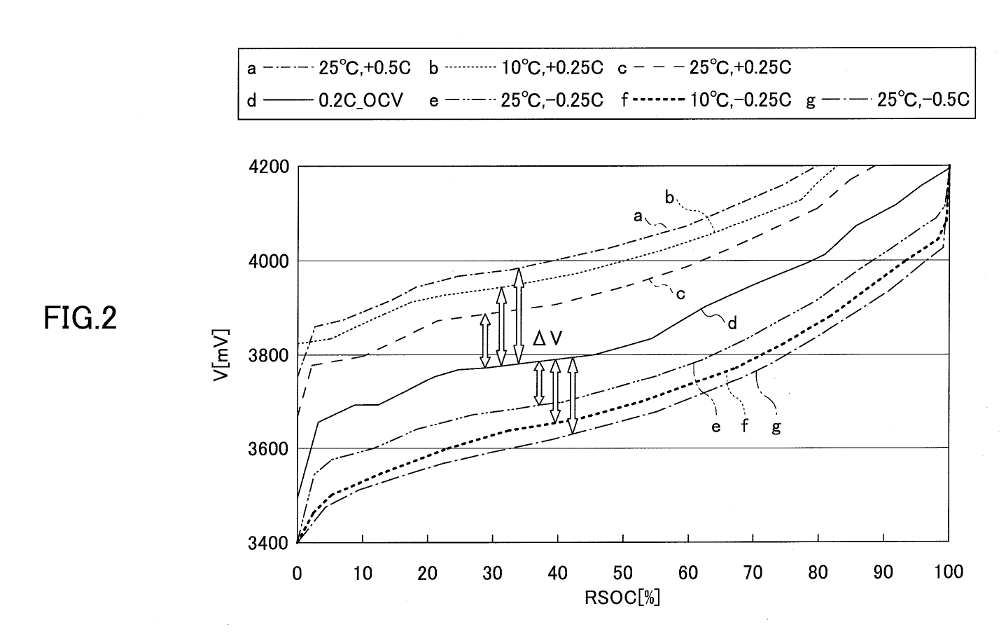

Next, a description will be given of the battery characteristics of the rechargeable battery 201. A curve representing a relationship between a charging rate and the battery voltage of the rechargeable battery 201 during the charging and discharge may differ depending on differences in the charge and discharge rates or differences in the ambient temperature, as illustrated in FIG. 2.

FIG. 2 is a diagram illustrating an example of a relationship between a RSOC (Relative State Of Charge) and the battery voltage at the time of charging and discharge of the rechargeable battery. The RSOC refers to a rate of the remaining capacity at the present temperature and current value, when a total amount dischargeable until a specific voltage (for example, 3.1 V) is reached from a fully charged state under the present temperature and current value is denoted by 100%. In FIG. 2, a curve “a” represents the characteristic when the charging is performed at a charging rate of 0.5 C at 25° C., a curve “b” represents the characteristic when the charging is performed at a charging rate of 0.25 C at 10° C., and a curve “c” represents the characteristic when the charging is performed at a charging rate of 0.25 C at 25° C. A curve “e” represents the characteristic when the discharge is performed at a discharge rate of 0.25 C at 25° C., a curve “f” represents the characteristic when the discharge is performed at a discharge rate of 0.25 C at 10° C., and a curve “g” represents the characteristic when the discharge is performed at a discharge rate of 0.5 C at 25° C. A curve “d” represents the characteristic of an open-circuit voltage OCV at 25° C. The open-circuit voltage OCV may be regarded as the battery voltage at a time when the charging and discharge of the rechargeable battery 201 stops.

According to the characteristics illustrated in FIG. 2, a voltage difference ΔV between the battery voltage V and the open-circuit voltage OCV of the rechargeable battery 201 becomes larger as the charging or discharge rate becomes higher, and becomes larger as the temperature T becomes lower, for each of the RSOCs. In other words, the charging or discharge rate has a correlation with the voltage difference ΔV and the temperature T for each of the RSOCs.

The battery capacity manager 40 of the measuring circuit 100 utilizes the above correlation, and computes the charging or discharge rate, that is, the variation (amount of increase or decrease) of the RSOC per unit time, based on correlation information, such as a function having the voltage difference ΔV and the temperature T as parameters, a table, or the like. When the amount of increase or decrease of the RSOC per unit time is computed, the RSOC of the unit time after may be computed based on the RSOC of the unit time before. By repeating the computing process described above for very unit time, it becomes possible to estimate RSOCs that are highly accurate and continuous.

In order for the battery capacity manager 40 to compute the voltage difference ΔV based on the battery voltage V detected by the voltage detector 10, the battery characteristic data corresponding to the curve “d” in FIG. 2 may preferably be obtained in advance as the battery characteristic data (zero reference voltage curve) that becomes a computation reference for the voltage difference ΔV. Further, in order for the battery capacity manager 40 to compute the amount of increase or decrease of the RSOC per unit time based on the computed value of the voltage difference ΔV and the temperature T detected by the temperature detector 20, the battery characteristic data that defines the relationship of the voltage difference ΔV and/or the temperature T and the amount of increase or decrease of the RSOC per unit time may be obtained in advance.

The battery characteristic data described above may differ for each type of the rechargeable battery 201. For this reason, with respect to the rechargeable battery 201 whose battery state is actually measured by the measuring circuit 100, the charging and discharge curves illustrated in FIG. 2 or the like may be measured in advance under the conditions of each temperature and each charging or discharge rate, in order to extract the battery characteristic data. The extracted battery characteristic data may be stored in the memory 50. The battery characteristic data prestored in the memory 50 may be used, together with the battery voltage value detected by the voltage detector 10 and the temperature value detected by the temperature detector 20, in order to compute the amount of increase or decrease of the RSOC per unit time. For example, when the temperature T is constant, a positive correlation exists between the amount of increase or decrease of the RSOC per unit time and the voltage difference ΔV, and the amount of increase or decrease of the RSOC per unit time that is computed becomes larger as the voltage difference ΔV becomes larger.

In order to estimate the RSOC to be 0% at a point in time when the battery voltage V of the rechargeable battery 201 reaches a lower limit of the operation voltage of the electronic apparatus 300, regardless of the operating conditions (temperature, load current) and the remaining capacity state of the rechargeable battery 201, the charging and discharge curves illustrated in FIG. 2 may be measured in advance, by regarding the capacity dischargeable from the fully charged state of the rechargeable battery 201 until the lower limit of the operation voltage of the electronic apparatus 300 is reached under each operating condition to be 100%.

The following is an example of a function that may be used to compute the amount of increase or decrease of the RSOC per unit time based on the computed value of the voltage difference ΔV and the temperature T detected by the temperature detector 20. In other words, an amount of increase or decrease, ΔRSOC, of the RSOC per unit time, may be represented by the following formula, where A, B, and C denote coefficients, and R denotes the temperature.

ΔRSOC={(A×T+B)×ΔV}+C

The above formula is an example of the function, and a second or higher order function may be used if preferable, for example. The function may include the value of the present RSOC as a variable. The values of the coefficients A, B, and C may change depending on the temperature T. In addition, the formula or the coefficients may be changed depending on a range the value of the variable takes. Hence, a suitable model function may be selected by taking into consideration the battery characteristics and the like that may differ for each type of the rechargeable battery 201. The memory 50 may prestore the coefficients of the function described above, or coefficients for determining the coefficients of the function.

Next, a description will be given of computing examples to compute the RSOC by the battery capacity manager 40.

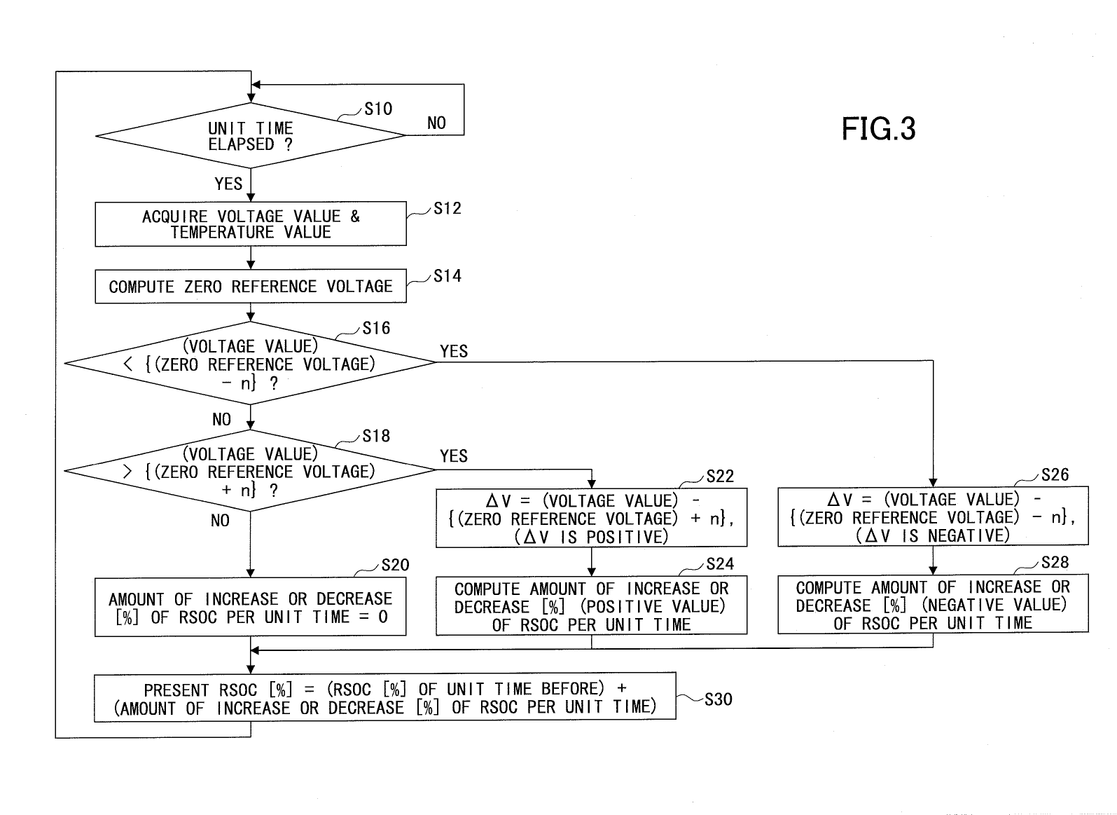

FIG. 3 is a flow chart for explaining a first computing example to compute the present RSOC. The battery capacity manager 40 uses the voltage computing unit 41, the voltage difference computing unit 42, the variation computing unit 43, and the charging rate computing unit 44, and repeatedly executes a routine represented by the flow chart of FIG. 3 for every unit time. In FIG. 3, n denotes a value that is zero or greater.

In a step S10, the battery capacity manager 40 judges whether a predetermined unit time elapsed. When the predetermined unit time elapses and the judgement result in the step 10 becomes YES, the battery capacity manager 40 starts a computing process of a step S12 and subsequent steps.

In the step S12, the battery capacity manager 40 acquires the battery voltage V detected by the voltage detector 10 and the temperature T detected by the temperature detector 20.

In the step S14, the voltage computing unit 41 computes a battery voltage at a time when the charging or discharge of the rechargeable battery 201 stops (hereinafter referred to as a “zero reference voltage”), from the RSOC of the unit time before (corresponding to a present RSOC computed in a step S30 of a previous routine). The voltage computing unit 41 reads from the memory 50 the battery characteristic data that determines the relationship between a zero battery voltage and the RSOC, and computes the zero reference voltage corresponding to the RSOC of the unit time before based on the read battery characteristic data.

In a step S16, the battery capacity manager 40 judges whether the battery voltage V acquired in the step S12 is lower than a value obtained by subtracting n from the zero reference voltage computed in the step S14. When the judgement result in the step S16 is YES, the present state of the rechargeable battery 201 exists in a region lower than the curve “d” in FIG. 2, and thus, the battery capacity manager 40 judges that the rechargeable battery 201 is in the discharge state.

In a step S26, the voltage difference computing unit 42 computes the voltage difference ΔV (the voltage difference ΔV takes a negative value in this case) by subtracting, from the battery voltage V acquired in the step S12, the value obtained by subtracting n from the zero reference voltage computed in the step S14.

In a step S28, the variation computing unit 43 reads from the memory 50 the battery characteristic data that determines the relationship of the voltage difference ΔV, the amount of increase or decrease of the RSOC per unit time, and the temperature T, and computes the amount of increase or decrease of the RSOC per unit time based on the read battery characteristic data. The variation computing unit 43 computes the amount of increase or decrease of the RSOC per unit time, corresponding to the voltage difference ΔV computed in the step S26 and the temperature T acquired in the step S12, based on the battery characteristic data.

In a step S18, the battery capacity manager 40 judges whether the battery voltage V acquired in the step S12 is higher than a value obtained by adding n to the zero reference voltage computed in the step S14. When the judgement result in the step S18 is YES, the present state of the rechargeable battery 201 exists in a region higher than the curve “d” in FIG. 2, and thus, the battery capacity manager 40 judges that the rechargeable battery 201 is in the charging state.

In a step S22, the voltage difference computing unit 42 computes the voltage difference ΔV (the voltage difference ΔV takes a positive value in this case) by subtracting, from the battery voltage V acquired in the step S12, the value obtained by adding n to the zero reference voltage computed in the step S14.

In a step S24, the variation computing unit 43 reads from the memory 50 the battery characteristic data that determines the relationship of the voltage difference ΔV, the amount of increase or decrease of the RSOC per unit time, and the temperature T, and computes the amount of increase or decrease of the RSOC per unit time based on the read battery characteristic data. The variation computing unit 43 computes the amount of increase or decrease of the RSOC per unit time, corresponding to the voltage difference ΔV computed in the step S22 and the temperature T acquired in the step S12, based on the battery characteristic data.

In a step S20, the battery capacity manager 40 sets the amount of increase or decrease of the RSOC per unit time to zero (or to a small value that is in a vicinity of zero and less than or equal to a predetermined value), when the battery voltage V acquired in the step S12 is higher than or equal to the value obtained by subtracting n from the zero reference voltage computed in the step S14 and the battery voltage V acquired in the step S12 is lower than or equal to the value obtained by adding n to the zero reference voltage computed in the step S14. In this case, the present state of the rechargeable battery 201 exists in a region on the curve “d” or in a vicinity of the curve “d” in FIG. 2, and thus, the battery capacity manager 40 judges that the rechargeable battery 201 is in a no-load state.

In the step S30, the charging rate computing unit 44 computes the present RSOC, by adding the RSOC of the unit time before (corresponding to the present RSOC computed in the step S30 of the previous routine) and the amount of increase or decrease of the RSOC per unit time computed in one of the steps S20, S24, and S28.

Accordingly, by repeating the routine illustrated in FIG. 3 for every unit time, it becomes possible to estimate RSOCs that are highly accurate and continuous.

Next, a description will be given of another method of estimating the RSOC.

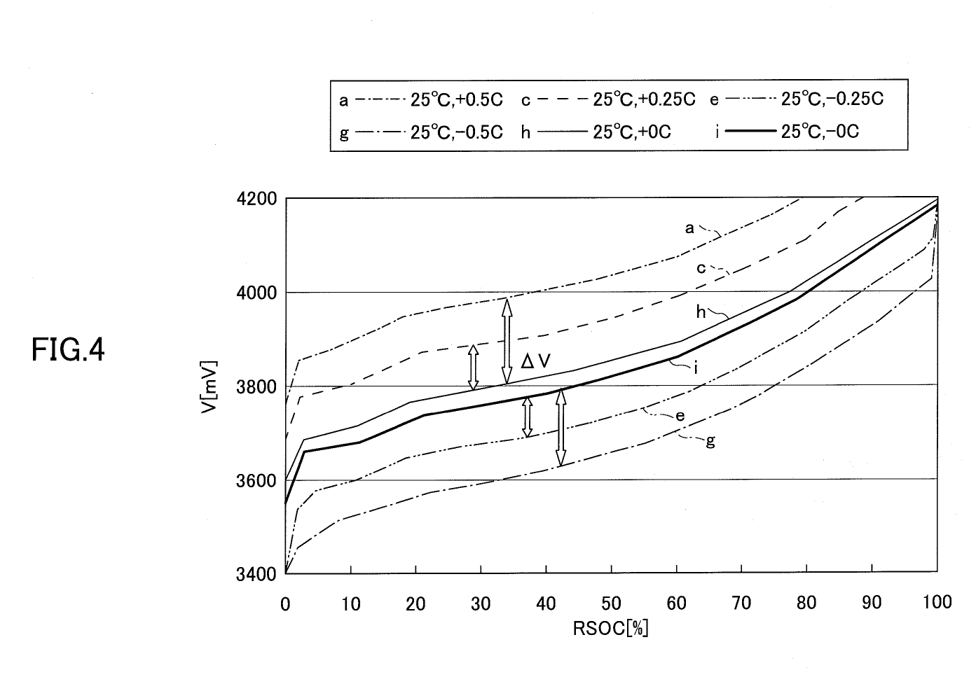

The method described above that estimates the RSOC using FIGS. 2 and 3 uses a single open-circuit voltage curve, such as the curve “d” in FIG. 2, as the zero reference voltage curve for computing the voltage difference ΔV, both at the time of the charging and at the time of the discharge. However, the characteristics displayed by the battery may be different at the time of the charging and at the time of the discharge, and thus, separate zero reference voltage curves may be provided for the charging and the discharge, as illustrated in FIG. 4.

FIG. 4 is a diagram illustrating another example of the relationship between the RSOC and the battery voltage at the time of charging and discharge of the rechargeable battery. In FIG. 4, a curve “a” represents the characteristic when the charging is performed at a charging rate of 0.5 C at 25° C., and a curve “c” represents the characteristic when the charging is performed at a charging rate of 0.25 C at 25° C. A curve “e” represents the characteristic when the discharge is performed at a discharge rate of 0.25 C at 25° C., and a curve “g” represents the characteristic when the discharge is performed at a discharge rate of 0.5 C at 25° C. A curve “h” represents the characteristic obtained from the battery characteristics at the time of the charging, such as the curves “a” and “c”, by making the charging rate close to 0 C as much as possible. A curve “i” represents the characteristic obtained from the battery characteristics at the time of the discharge, such as the curves “e” and “g”, by making the discharge rate close to 0 C as much as possible. The curve “h” may be regarded as the battery characteristics at the time when the charging stops, and the curve “i” may be regarded as the battery characteristics at the time when the discharge stops.

By utilizing the curves “h” and “i” as the zero reference voltage curves, the charging rate (that is, the amount of increase of the charging rate per unit time) and the discharge rate (that is, the amount of decrease of the charging rate per unit time) may be obtained more accurately when compared to the case illustrated in FIG. 2.

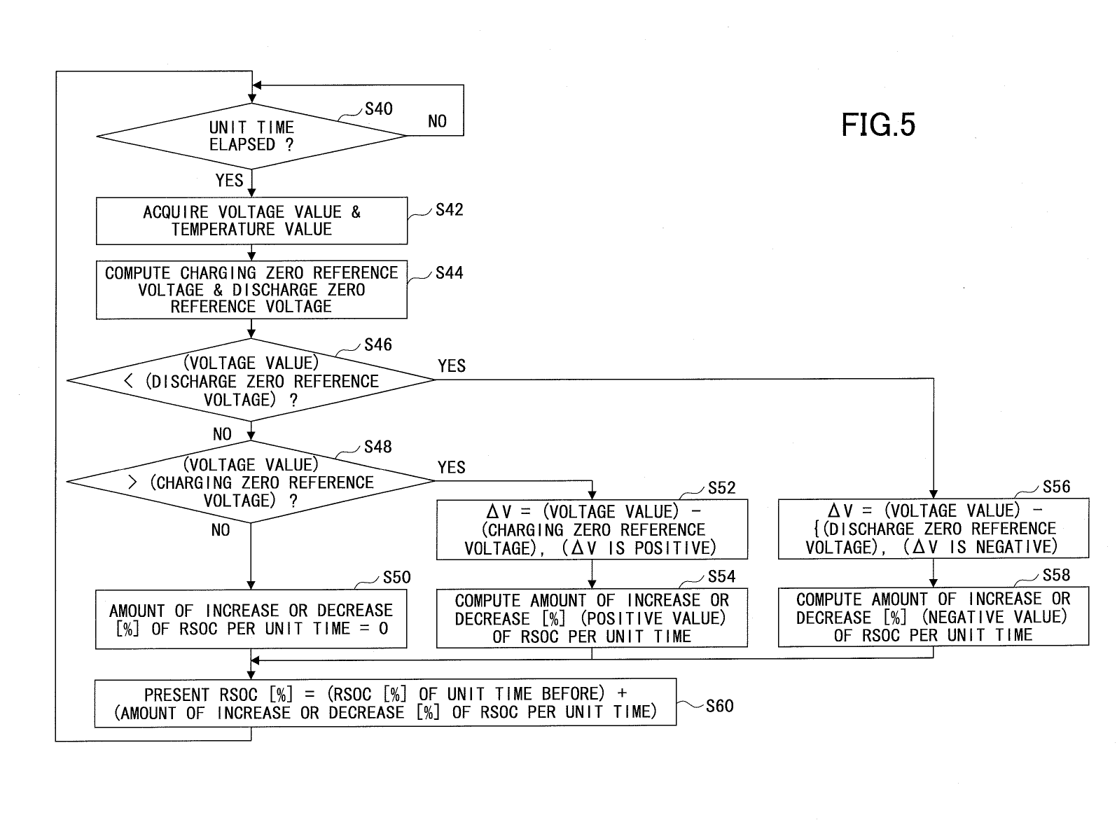

FIG. 5 is a flow chart for explaining a second computing example to compute the present RSOC. The battery capacity manager 40 uses the voltage computing unit 41, the voltage difference computing unit 42, the variation computing unit 43, and the charging rate computing unit 44, and repeatedly executes a routine represented by the flow chart of FIG. 5 for every unit time.

In a step S40, the battery capacity manager 40 judges whether a predetermined unit time elapsed. When the predetermined unit time elapses and the judgement result in the step 40 becomes YES, the battery capacity manager 40 starts a computing process of a step S42 and subsequent steps.

In the step S42, the battery capacity manager 40 acquires the battery voltage V detected by the voltage detector 10 and the temperature T detected by the temperature detector 20.

In the step S44, the voltage computing unit 41 computes a battery voltage at a time when the charging of the rechargeable battery 201 stops (hereinafter referred to as a “charging zero reference voltage”), from the RSOC of the unit time before (corresponding to a present RSOC computed in a step S60 of a previous routine). The voltage computing unit 41 reads from the memory 50 the battery characteristic data that determines the relationship between a charging zero battery voltage and the RSOC, and computes the charging zero reference voltage corresponding to the RSOC of the unit time before based on the read battery characteristic data. Similarly, the voltage computing unit 41 computes a battery voltage at a time when the discharge of the rechargeable battery 201 stops (hereinafter referred to as a “discharge zero reference voltage”), from the RSOC of the unit time before (corresponding to the present RSOC computed in the step S60 of the previous routine). The voltage computing unit 41 reads from the memory 50 the battery characteristic data that determines the relationship between a discharge zero battery voltage and the RSOC, and computes the discharge zero reference voltage corresponding to the RSOC of the unit time before based on the read battery characteristic data.

In a step S46, the battery capacity manager 40 judges whether the battery voltage V acquired in the step 542 is lower than the discharge zero reference voltage computed in the step S44. When the judgement result in the step S46 is YES, the present state of the rechargeable battery 201 exists in a region lower than the curve “i” in FIG. 4, and thus, the battery capacity manager 40 judges that the rechargeable battery 201 is in the discharge state.

In a step S56, the voltage difference computing unit 42 computes the voltage difference ΔV (the voltage difference ΔV takes a negative value in this case) by subtracting, from the battery voltage V acquired in the step S12, the discharge zero reference voltage computed in the step S44.

In a step S58, the variation computing unit 43 reads from the memory 50 the battery characteristic data that determines the relationship of the voltage difference ΔV between the battery voltage and the discharge zero reference voltage, the amount of increase or decrease of the RSOC per unit time, and the temperature T, and computes the amount of increase or decrease of the RSOC per unit time based on the read battery characteristic data. The variation computing unit 43 computes the amount of increase or decrease of the RSOC per unit time, corresponding to the voltage difference ΔV computed in the step S56 and the temperature T acquired in the step 542, based on the battery characteristic data.

In a step S48, the battery capacity manager 40 judges whether the battery voltage V acquired in the step S42 is higher than the charging zero reference voltage computed in the step S44. When the judgement result in the step S48 is YES, the present state of the rechargeable battery 201 exists in a region higher than the curve “h” in FIG. 4, and thus, the battery capacity manager 40 judges that the rechargeable battery 201 is in the charging state.

In a step S52, the voltage difference computing unit 42 computes the voltage difference ΔV (the voltage difference ΔV takes a positive value in this case) by subtracting, from the battery voltage V acquired in the step S12, the charging zero reference voltage computed in the step S44.

In a step S54, the variation computing unit 43 reads from the memory 50 the battery characteristic data that determines the relationship of the voltage difference ΔV between the battery voltage and the charging zero reference voltage, the amount of increase or decrease of the RSOC per unit time, and the temperature T, and computes the amount of increase or decrease of the RSOC per unit time based on the read battery characteristic data. The variation computing unit 43 computes the amount of increase or decrease of the RSOC per unit time, corresponding to the voltage difference ΔV computed in the step S52 and the temperature T acquired in the step S42, based on the battery characteristic data.

In a step S50, the battery capacity manager 40 sets the amount of increase or decrease of the RSOC per unit time to zero (or to a small value that is in a vicinity of zero and less than or equal to a predetermined value), when the battery voltage V acquired in the step S42 is higher than or equal to the discharge zero reference voltage computed in the step S44 and the battery voltage V acquired in the step S42 is lower than or equal to the charging zero reference voltage computed in the step S44. In this case, the present state of the rechargeable battery 201 exists in a region between the curves “i” and “h” in FIG. 4, and thus, the battery capacity manager 40 judges that the rechargeable battery 201 is in a no-load state.

In the step S60, the charging rate computing unit 44 computes the present RSOC, by adding the RSOC of the unit time before (corresponding to the present RSOC computed in the step S60 of the previous routine) and the amount of increase or decrease of the RSOC per unit time computed in one of the steps S50, S54, and S58.

Accordingly, by repeating the routine illustrated in FIG. 5 for every unit time, it becomes possible to estimate RSOCs that are highly accurate and continuous.

In FIGS. 3 and 5, the method of obtaining an initial value of the RSOC immediately after the power is turned ON may use a function or a table representing a curve that relates the battery voltage (for example, open-circuit voltage) at the time of the no-load state and the RSOC with a 1:1 correspondence, and convert the battery detected by the voltage detector 10 into the corresponding RSOC value.

According to the embodiments described above, the following advantageous features 1 through 5 may be obtained.

1. The battery state may be judged to be one of three kinds of states, namely, the charging state, the no-load state, and the discharge state, from the relationship between the present RSOC and the battery voltage value.

2. The RSOC may constantly be estimated by repeating, for very unit time, a process of computing the amount of increase or decrease of the RSOC per unit time from the relationship of the present RSOC, the battery voltage value, and the temperature, and predicting the RSOC of the unit time after.

3. By providing separate battery characteristic data, such as the zero reference voltage obtained from the present RSOC, for the charging and the discharge, the RSOC may be estimated with a higher accuracy.

4. By tolerating a certain range for the battery voltage in judging the no-load state, a change in the RSOC caused by the voltage being restored after the charging or discharge stops may be suppressed.

5. By estimating the RSOC to be 0% at the time when the battery voltage during the discharge reaches a predetermined voltage value, regardless of the operating conditions (temperature, load current), the RSOC until the apparatus using the battery reaches the lower limit of the operation voltage may constantly be estimated regardless of the operating conditions.

By computing the amount of increase or decrease of the RSOC per unit time using the battery characteristic data, based on the relationship of the present RSOC, the battery voltage, and the temperature of the rechargeable battery, it becomes possible to estimate RSOCs that are highly accurate and continuous under various operating conditions.

In addition, the following advantageous features 6 and 7 may also be obtained.

6. When the estimated value of the RSOC during the discharge is higher than the actual RSOC, the estimated value of the discharge rate that is computed is also higher than the actual discharge rate. In addition, when the estimated value of the RSOC during the discharge is lower than the actual RSOC, the estimated value of the discharge rate that is computed is also lower than the actual discharge rate. Hence, an estimation error converges in a direction so as to decrease the estimation error.

7. Similarly, when the estimated value of the RSOC during the charging is higher than the actual RSOC, the estimated value of the charging rate that is computed is lower than the actual discharge rate. In addition, when the estimated value of the RSOC during the charging is lower than the actual RSOC, the estimated value of the charging rate that is computed is higher than the actual discharge rate. Hence, the estimation error converges in a direction so as to decrease the estimation error.

Accordingly, the estimation error does not diverge, and converges in the direction so as to decrease the estimation error, even under the actual, various operating conditions (repetition of various charging or discharge).

Furthermore, the following advantageous feature may also be obtained.

8. A remaining time [s] may be obtained from the following formula, using the estimated RSOC, the amount of increase or decrease of the RSOC per unit time, ΔRSOC [%/s].

Remaining Time [s]=(RSOC [%])/(ΔRSOC [%/s])

Although preferable embodiments of the present invention are described above, the present invention is not limited to the embodiments described above, and various variations, modifications, and substitutions may be made without departing from the scope of the present invention.

For example, in one embodiment, the battery state measuring apparatus is not limited to being mounted on a substrate within the electronic apparatus 300 that may operate using the rechargeable battery 201. The battery state measuring apparatus may be mounted on a substrate of the protection module 202 within the battery pack 200, for example. Moreover, in one embodiment, the battery state measuring method may be realized by embedding, in the CPU 301 within the electronic apparatus 300, software that causes the CPU 301 to execute steps or procedures of the battery state measuring method.

In addition, the embodiment is not limited to using the RSOC, and an absolute state of charge may be estimated in place of the RSOC. The absolute state of charge refers to a rate of the remaining capacity at a given temperature and current value (for example, 25° C. and 0.2 C), when a total amount dischargeable until a specific voltage (for example, 3.1 V) is reached from a fully charged state under the given temperature and current value is denoted by 100%.

Further, the amount of increase or decrease of the charging rate per unit time may be computed without taking the temperature T into consideration. For example, the variation computing unit 43 may read from the memory 50 the battery characteristic data determining the relationship of the voltage difference ΔV between the battery voltage and the discharge zero reference voltage (or charging zero reference voltage), and the amount of increase or decrease of the RSOC per unit time, and compute the amount of increase or decrease of the RSOC per unit time based on the read battery characteristic data. The variation computing unit 43 compute the amount of increase or decrease of the RSOC per unit time corresponding to the voltage difference ΔV, based on the battery characteristic data.

What is claimed is:

1. A battery state measuring method comprising:
detecting a battery voltage of a rechargeable battery;
computing a battery voltage at a time when charging or discharge of the rechargeable battery stops, corresponding to a charging rate of the rechargeable battery of a unit time before, based on a first battery characteristic that determines a relationship between the charging rate and the battery voltage at the time when the charging or discharge of the rechargeable battery stops;
computing a voltage difference between the battery voltage detected by the detecting and the battery voltage computed by the battery voltage computing;
computing a variation per unit time of the charging rate of the rechargeable battery, corresponding to the voltage difference computed by the voltage difference computing, based on a second battery characteristic that determines a relationship of a voltage difference between the battery voltage at the time when the charging or discharge of the rechargeable battery stops and the battery voltage detected by the detecting, and a variation per unit time of the charging rate of the rechargeable battery; and
computing a charging rate of the rechargeable battery of the unit time after, using the charging rate of the rechargeable battery of the unit time before and the variation computed by the variation computing.

2. The battery state measuring method as claimed in claim 1, wherein the first battery characteristic includes
a third battery characteristic that determines a relationship between the charging rate and the battery voltage at a time when the charging of the rechargeable battery stops, and
a fourth battery characteristic that determines a relationship between the charging rate and the battery voltage at a time when the discharge of the rechargeable battery stops, and
wherein the battery voltage computing includes
computing the battery voltage at the time when the charging of the rechargeable battery stops, corresponding to the charging rate of the rechargeable battery of the unit time before, based on the third battery characteristic, and
computing the battery voltage at the time when the discharge of the rechargeable battery stops, corresponding to the charging rate of the rechargeable battery of the unit time before, based on the fourth battery characteristic.

3. The battery state measuring method as claimed in claim 2, wherein the second battery characteristic includes
a fifth battery characteristic that determines a relationship of the voltage difference between the battery voltage at the time when the charging of the rechargeable battery stops and the battery voltage detected by the detecting, and the variation per unit time of the charging rate of the rechargeable battery, and
a sixth battery characteristic that determines a relationship of the voltage difference between the battery voltage at the time when the discharge of the rechargeable battery stops and the battery voltage detected by the detecting, and the variation per unit time of the charging rate of the rechargeable battery, and
wherein the variation computing includes
computing the variation per unit time of the charging rate of the rechargeable battery, corresponding to the voltage difference computed by the voltage difference computing, based on the fifth battery characteristic, and
computing the variation per unit time of the charging rate of the rechargeable battery, corresponding to the voltage difference computed by the voltage difference computing, based on the sixth battery characteristic.

4. The battery state measuring method as claimed in claim 1, further comprising:
detecting a temperature of the rechargeable battery,
wherein the second battery characteristic determines a relationship of the voltage difference between the battery voltage at the time when the charging or discharge of the rechargeable battery stops and the battery voltage detected by the detecting, the variation per unit time of the charging rate of the rechargeable battery, and the temperature of the rechargeable battery detected by the temperature detecting, and
wherein the variation computing computes the variation per unit time of the charging rate of the rechargeable battery, corresponding to the voltage difference computed by the voltage difference computing and the temperature of the rechargeable battery detected by the temperature detecting.

5. The battery state measuring method as claimed in claim 4, wherein the second battery characteristic includes
a seventh battery characteristic that determines a relationship of the voltage difference between the battery voltage at the time when the charging of the rechargeable battery stops and the battery voltage detected by the detecting, the variation per unit time of the charging rate of the rechargeable battery, and the temperature of the rechargeable battery, and
an eighth battery characteristic that determines a relationship of the voltage difference between the battery voltage at the time when the discharge of the rechargeable battery stops and the battery voltage detected by the detecting, the variation per unit time of the charging rate of the rechargeable battery, and the temperature of the rechargeable battery, and
wherein the variation computing includes
computing the variation per unit time of the charging rate of the rechargeable battery, corresponding to the voltage difference computed by the voltage difference computing and the temperature detected by the temperature detecting, based on the seventh battery characteristic, and
computing the variation per unit time of the charging rate of the rechargeable battery, corresponding to the voltage difference computed by the voltage difference computing and the temperature detected by the temperature detecting, based on the eighth battery characteristic.

6. The battery state measuring method as claimed in claim 1, wherein a routine including the detecting, the voltage computing, the voltage difference computing, the variation computing, and the charging rate computing is repeated for every unit time.

7. The battery state measuring method as claimed in claim 4, wherein a routine including the detecting, the voltage computing, the voltage difference computing, the variation computing, the charging rate computing, and the temperature detecting is repeated for every unit time.

8. The battery state measuring method as claimed in claim 1, wherein the variation computing sets the variation per unit time of the charging rate of the rechargeable battery to a value less than or equal to a predetermined value, when the voltage difference computed by the voltage difference computing is less than or equal to a predetermine voltage.

9. A battery state measuring apparatus comprising:
a voltage detector configured to detect a battery voltage of a rechargeable battery;
a voltage computing unit configured to compute a battery voltage at a time when charging or discharge of the rechargeable battery stops, corresponding to a charging rate of the rechargeable battery of a unit time before, based on a first battery characteristic that determines a relationship between the charging rate and the battery voltage at the time when the charging or discharge of the rechargeable battery stops;
a voltage difference computing unit configured to compute a voltage difference between the battery voltage detected by the voltage detector and the battery voltage computed by the voltage computing unit;
a variation computing unit configured to compute a variation per unit time of the charging rate of the rechargeable battery, corresponding to the voltage difference computed by the voltage difference computing unit, based on a second battery characteristic that determines a relationship of a voltage difference between the battery voltage at the time when the charging or discharge of the rechargeable battery stops and the battery voltage detected by the voltage detector, and a variation per unit time of the charging rate of the rechargeable battery; and
a charging rate computing unit configured to compute a charging rate of the rechargeable battery of the unit time after, using the charging rate of the rechargeable battery of the unit time before and the variation computed by the variation computing unit.

10. The battery state measuring apparatus as claimed in claim 9, wherein the first battery characteristic includes
a third battery characteristic that determines a relationship between the charging rate and the battery voltage at a time when the charging of the rechargeable battery stops, and
a fourth battery characteristic that determines a relationship between the charging rate and the battery voltage at a time when the discharge of the rechargeable battery stops, and
wherein the battery voltage computing unit
computes the battery voltage at the time when the charging of the rechargeable battery stops, corresponding to the charging rate of the rechargeable battery of the unit time before, based on the third battery characteristic, and
computes the battery voltage at the time when the discharge of the rechargeable battery stops, corresponding to the charging rate of the rechargeable battery of the unit time before, based on the fourth battery characteristic.

11. The battery state measuring apparatus as claimed in claim 10, wherein the second battery characteristic includes
a fifth battery characteristic that determines a relationship of the voltage difference between the battery voltage at the time when the charging of the rechargeable battery stops and the battery voltage detected by the voltage detector, and the variation per unit time of the charging rate of the rechargeable battery, and
a sixth battery characteristic that determines a relationship of the voltage difference between the battery voltage at the time when the discharge of the rechargeable battery stops and the battery voltage detected by the voltage detector, and the variation per unit time of the charging rate of the rechargeable battery, and
wherein the variation computing unit
computes the variation per unit time of the charging rate of the rechargeable battery, corresponding to the voltage difference computed by the voltage difference computing unit, based on the fifth battery characteristic, and
computes the variation per unit time of the charging rate of the rechargeable battery, corresponding to the voltage difference computed by the voltage difference computing unit, based on the sixth battery characteristic.

12. The battery state measuring apparatus as claimed in claim 9, further comprising:
a temperature detector configured to detect a temperature of the rechargeable battery,
wherein the second battery characteristic determines a relationship of the voltage difference between the battery voltage at the time when the charging or discharge of the rechargeable battery stops and the battery voltage detected by the voltage detector, the variation per unit time of the charging rate of the rechargeable battery, and the temperature of the rechargeable battery detected by the temperature detector, and
wherein the variation computing unit computes the variation per unit time of the charging rate of the rechargeable battery, corresponding to the voltage difference computed by the voltage difference computing unit and the temperature of the rechargeable battery detected by the temperature detector.

13. The battery state measuring apparatus as claimed in claim 12, wherein the second battery characteristic includes
a seventh battery characteristic that determines a relationship of the voltage difference between the battery voltage at the time when the charging of the rechargeable battery stops and the battery voltage detected by the voltage detector, the variation per unit time of the charging rate of the rechargeable battery, and the temperature of the rechargeable battery, and
an eighth battery characteristic that determines a relationship of the voltage difference between the battery voltage at the time when the discharge of the rechargeable battery stops and the battery voltage detected by the voltage detector, the variation per unit time of the charging rate of the rechargeable battery, and the temperature of the rechargeable battery, and
wherein the variation computing unit
computes the variation per unit time of the charging rate of the rechargeable battery, corresponding to the voltage difference computed by the voltage difference computing unit and the temperature detected by the temperature detector, based on the seventh battery characteristic, and
computes the variation per unit time of the charging rate of the rechargeable battery, corresponding to the voltage difference computed by the voltage difference computing unit and the temperature detected by the temperature detector, based on the eighth battery characteristic.

14. The battery state measuring apparatus as claimed in claim 9, wherein a routine executed by the voltage detector, the voltage computing unit, the voltage difference computing unit, the variation computing unit, and the charging rate computing unit is repeated for every unit time.

15. The battery state measuring apparatus as claimed in claim 12, wherein a routine executed by the voltage detector, the voltage computing unit, the voltage difference computing unit, the variation computing unit, the charging rate computing unit, and the temperature detector is repeated for every unit time.

16. The battery state measuring apparatus as claimed in claim 9, wherein the variation computing unit sets the variation per unit time of the charging rate of the rechargeable battery to a value less than or equal to a predetermined value, when the voltage difference computed by the voltage difference computing unit is less than or equal to a predetermine voltage.

17. A battery protection unit comprising:
the battery state measuring apparatus as claimed in claim 9; and
a protection circuit configured to protect the rechargeable battery.

18. A battery pack comprising:
the battery state measuring apparatus as claimed in claim 9; and
the rechargeable battery.

19. An electronic apparatus comprising:
the battery state measuring apparatus as claimed in claim 9,
wherein the electronic apparatus receives power from the rechargeable battery.
